(19) United States
(12) Patent Application Publication
(10) Pub. No.: US 2026/0344001 A1
(43) Pub. Date: Oct. 29, 2026

(54) METAL GATES WITH CUT-METAL-BOUNDARY STRUCTURES AND THE METHODS OF FORMING THE SAME

(71) Applicants: Taiwan Semiconductor Manufacturing Co., Ltd, Hsinchu (TW); TSMC Arizona Corporation, Phoenix, AZ (US)

(72) Inventors: Tso-Hsuan Chen, Phoenix, AZ (US); Tsung-Chieh Hsiao, Shetou Township (TW); Wei-Yuan Lee, Hsinchu (TW); Chih-Lin Wang, Zhubei City (TW)

(21) Appl. No.: 19/732,784

(22) Filed: Jul. 7, 2026

Related U.S. Application Data
(63) Continuation of application No. 18/918,708, filed on Oct. 17, 2024.
(60) Provisional application No. 63/672,746, filed on Jul. 18, 2024.

(51) Int. Cl. H10D 64/66; H10D 30/62; H10D 64/01; H10D 84/85

(52) U.S. Cl. CPC H10D 64/666; H10D 64/01316; H10D 84/856; H10D 30/62

(57) ABSTRACT

A method includes forming a first gate dielectric and a second gate dielectric over a first semiconductor region and a second semiconductor region, respective, forming a first work-function layer comprising a first portion and a second portion over the first gate dielectric and the second gate dielectric, respectively, patterning the first work-function layer to remove the second portion of the first work-function layer, and forming a second work-function layer comprising a first portion and a second portion over the first gate dielectric and the second gate dielectric, respectively. The method further includes performing an etching process to etch the second work-function layer and a part of the first portion of the first work-function layer to form an opening, and depositing a conductive layer over the second work-function layer. The conductive layer is filled into the opening.

### PRIORITY CLAIM AND CROSS-REFERENCE

This application is a continuation of U.S. patent application Ser. No. 18/918,708, filed Oct. 17, 2024, and entitled “METAL GATES WITH CUT-METAL-BOUNDARY STRUCTURES AND THE METHODS OF FORMING THE SAME,” which claims the benefit of U.S. Provisional Application No. 63/672,746, filed on Jul. 18, 2024, and entitled “CMB STRUCTURE FOR PREVENTING MBE,” which application are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6, 7A, 7B, and 8-17 illustrate the views of intermediate stages in the formation of transistors including cut-metal-boundary regions in accordance with some embodiments.

FIG. 18 illustrates a top view of some transistors in accordance with some embodiments.

FIGS. 19 and 20 illustrate schematic views of circuit regions including and circuit regions not including cut-metal-boundary regions in accordance with some embodiments.

FIG. 21 illustrates a view of gate-all-around transistors including a cut-metal-boundary region in accordance with some embodiments.

FIG. 22 illustrates a layout of a Static Random-Access Memory (SRAM) cell including cut-metal-boundary regions in accordance with some embodiments.

FIG. 23 illustrates a process flow for forming transistors including cut-metal-boundary regions in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Transistors including Cut-Metal-Boundary (CMB) regions and the method of forming the same are provided. In accordance with some embodiments, a p-type transistor and an n-type transistor are formed as having their gate stacks joined with each other. A high-k dielectric layer, which includes a first portion in the p-type transistor and a second portion in the n-type transistor, is cut apart to form a recess that separates the first portion from the second portion. The cutting may be performed after the formation of an aluminum-containing material, which is used as the work-function layer of the n-type transistor. The subsequently formed adhesion layer and metal-filling region thus include some parts filling the respective recess to form the CMB region. By forming the CMB region, the otherwise diffusion of aluminum into the high-k dielectric of the p-type transistor is reduced, and the adverse increase of the threshold voltage of the p-type transistor is reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

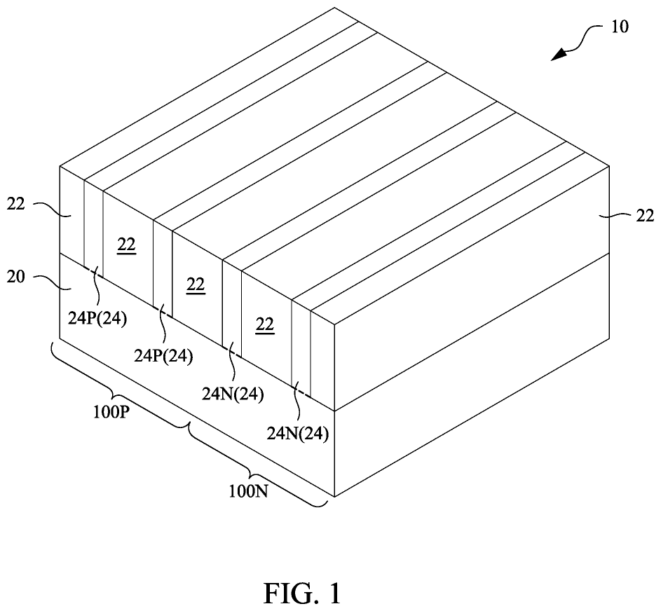

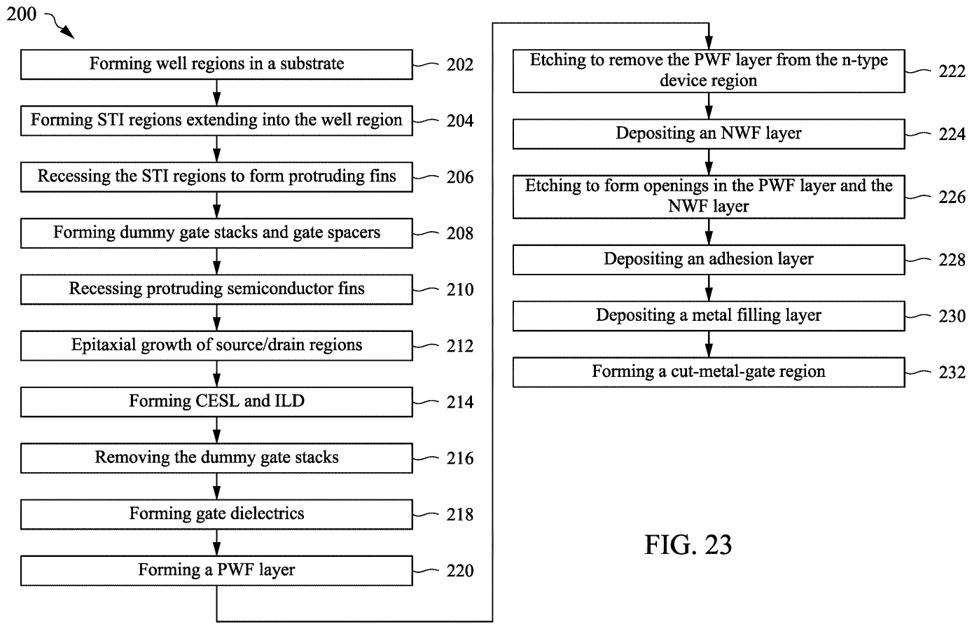

FIGS. 1 through 17 illustrate the views of intermediate stages in the formation of p-type transistors and n-type transistors in accordance with some embodiments of the present disclosure. The corresponding processes are also reflected schematically in the process flow shown in FIG. 23.

FIG. 1 illustrates a perspective view in the formation of an initial structure. The initial structure includes wafer 10, which further includes substrate 20. Substrate 20 may be a semiconductor substrate, which may be a silicon substrate, a silicon germanium substrate, or a substrate formed of other semiconductor materials. Substrate 20 may be doped with a p-type or an n-type dopant.

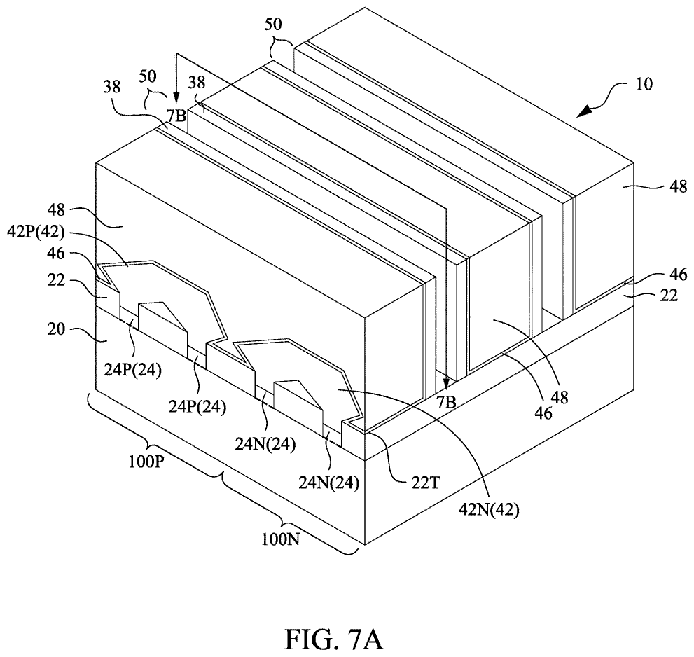

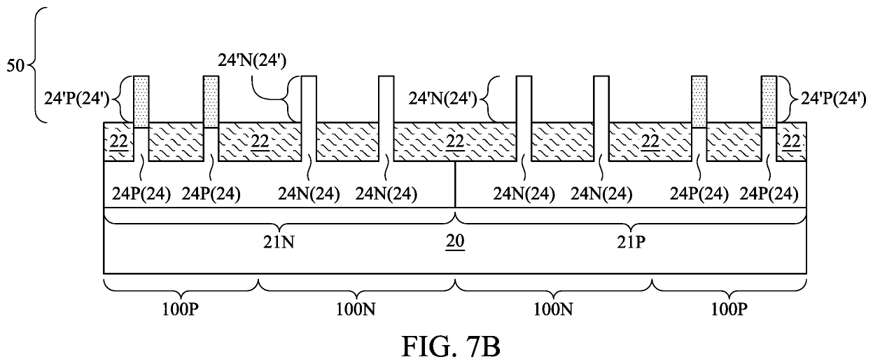

Wafer 10 includes device region 100P, in which a p-type transistor is to be formed, and device region 100N, in which an n-type transistor is to be formed. The device region 100P may include a well region 21N (not shown in FIG. 1, refer to FIG. 7B), which is an n-type region. The device region 100N may also include well region 21P (not shown in FIG. 1, refer to FIG. 7B), which is a p-type region. The well region 21N and 21P may be formed through implantation processes. The respective process is illustrated as process 202 in the process flow 200 as shown in FIG. 23.

Isolation regions 22 such as Shallow Trench Isolation (STI) regions may be formed to extend from a top surface of substrate 20 into substrate 20. The respective process is illustrated as process 204 in the process flow 200 as shown in FIG. 23. The portions of substrate 20 between neighboring STI regions 22 are referred to as semiconductor strips 24, wherein the well regions extend into the semiconductor strips 24. The top surfaces of semiconductor strips 24 and the top surfaces of STI regions 22 may be substantially level with each other in accordance with some embodiments. The portion of semiconductor substrate 20 lower than STI regions 22 is referred to as a bulk portion of the semiconductor substrate 20, or a bulk semiconductor substrate.

Throughout the description, the semiconductor strips 24 in device region 100P are referred to as semiconductor strips 24P, and the semiconductor strips 24 in device region 100N are referred to as semiconductor strips 24N. In accordance with some embodiments, semiconductor strips 24 are parts of the original substrate 20, and hence the material of semiconductor strips 24 is the same as that of substrate 20.

In accordance with alternative embodiments, semiconductor strips 24 are replacement strips formed by etching the portions of substrate 20 between STI regions 22 to form recesses, and performing an epitaxy process to regrow another semiconductor material in the recesses. Accordingly, semiconductor strips 24P and/or 24N may be formed of semiconductor materials different from that of substrate 20. In accordance with some embodiments, semiconductor strips 24 are formed of silicon germanium, carbon-doped silicon, or a III-V compound semiconductor material. For example, the top portions of semiconductor strips 24P may comprise SiGe, and the top portions of semiconductor strips 24N may comprise Si.

STI regions 22 may include a liner oxide (not shown), which may be a thermal oxide formed through the thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), Chemical Vapor Deposition (CVD), or the like. STI regions 22 may also include a dielectric material over the liner oxide, wherein the dielectric material may be formed using Flowable Chemical Vapor Deposition (FCVD), spin-on, or the like.

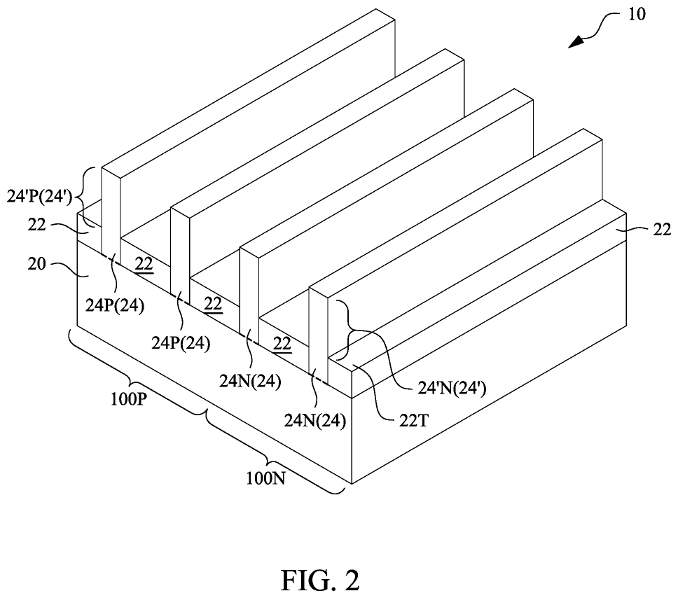

Referring to FIG. 2, STI regions 22 are recessed, so that the top portions of semiconductor strips 24 protrude higher than the top surfaces 22T of the remaining portions of STI regions 22 to form protruding fins 24′. The respective process is illustrated as process 206 in the process flow 200 as shown in FIG. 23. Protruding fins 24′ include protruding fins 24′P in device region 100P, and protruding fins 24′N in device region 100N. The etching may be performed using a dry etching process, wherein HF and NH₃, for example, may be used as the etching gases. During the etching process, plasma may be generated. Argon may also be included. In accordance with alternative embodiments of the present disclosure, the recessing of STI regions 22 is performed using a wet etch process. The etching chemical may include HF, for example.

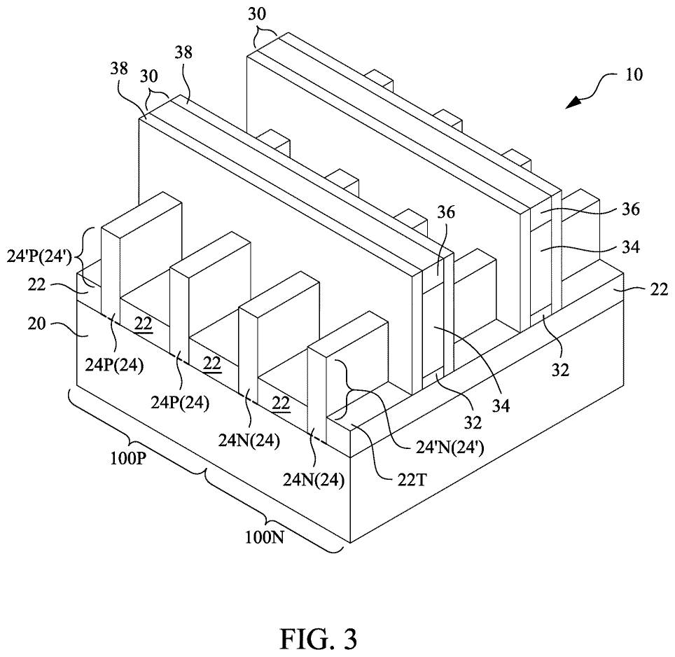

Referring to FIG. 3, dummy gate stacks 30 are formed on the top surfaces and the sidewalls of (protruding) fins 24′. The respective process is illustrated as process 208 in the process flow 200 as shown in FIG. 23. Dummy gate stacks 30 may include dummy gate dielectrics 32 and dummy gate electrodes 34 over dummy gate dielectrics 32. Dummy gate dielectrics 32 may be formed of or comprise silicon oxide. Dummy gate electrodes 34 may be formed, for example, using polysilicon or amorphous silicon, and other materials may also be used. Each of dummy gate stacks 30 may also include one (or a plurality of) hard mask layer 36 over dummy gate electrodes 34. Hard mask layers 36 may be formed of silicon nitride, silicon oxide, silicon carbo-nitride, or multi-layers thereof. Dummy gate stacks 30 may cross over a plurality of protruding fins 24′ and STI regions 22. Dummy gate stacks 30 also have lengthwise directions perpendicular to the lengthwise directions of protruding fins 24′.

Next, gate spacers 38 are formed on the sidewalls of dummy gate stacks 30. In accordance with some embodiments of the present disclosure, gate spacers 38 are formed of a dielectric material such as silicon nitride, silicon carbo-nitride, or the like, and may have a single-layer structure or a multi-layer structure including a plurality of dielectric layers.

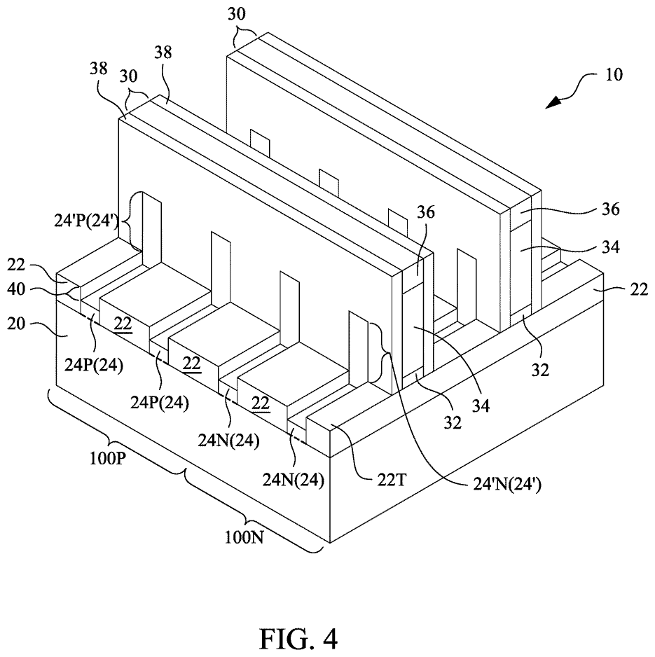

A recessing process is then performed to etch the portions of protruding fins 24′ that are not covered by dummy gate stacks 30 and gate spacers 38, resulting in the structure shown in FIG. 4. The respective process is illustrated as process 210 in the process flow 200 as shown in FIG. 23. The recessing may be anisotropic, and hence the portions of fins 24′ directly underlying dummy gate stacks 30 and gate spacers 38 are protected, and are not etched. The top surfaces of the recessed semiconductor strips 24 may be lower than the top surfaces 22T of STI regions 22 in accordance with some embodiments. Recesses 40 are accordingly formed between STI regions 22. Recesses 40 are located on the opposite sides of dummy gate stacks 30.

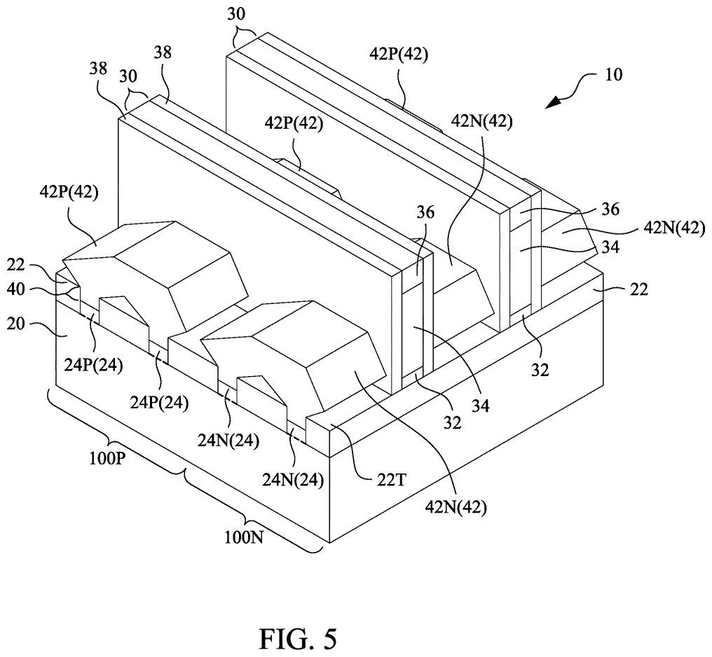

Next, epitaxy regions (source/drain regions) 42 are formed by selectively growing a semiconductor material from recesses 40, resulting in the structure in FIG. 5. The respective process is illustrated as process 212 in the process flow 200 as shown in FIG. 23. Source/drain region(s) may refer to a source or a drain, individually or collectively dependent upon the context.

Source/drain regions 42 include p-type source/drain regions 42P and n-type source/drain regions 42N, which are formed separately through separate epitaxy processes. P-type source/drain regions 42P may include SiGeB, SiB, SiGeIn, SiIn, or the like. N-type source/drain regions 42N may include SiP, SiCP, SiAs, SiCAs, or the like. After epitaxy regions 42 fully fill recesses 40, epitaxy regions 42 start expanding horizontally, and facets may be formed.

After the epitaxy process, epitaxy regions 42 may be further implanted with a p-type or an n-type impurity (depending the conductivity type of the epitaxy regions 42) to form source and drain regions, which are also denoted using reference numeral 42. In accordance with alternative embodiments of the present disclosure, the implantation process is skipped when epitaxy regions 42 are in-situ doped with the p-type or n-type impurity during the epitaxy to form source/drain regions. Epitaxy source/drain regions 42 include lower portions that are formed in STI regions 22, and upper portions that are formed over the top surfaces of STI regions 22.

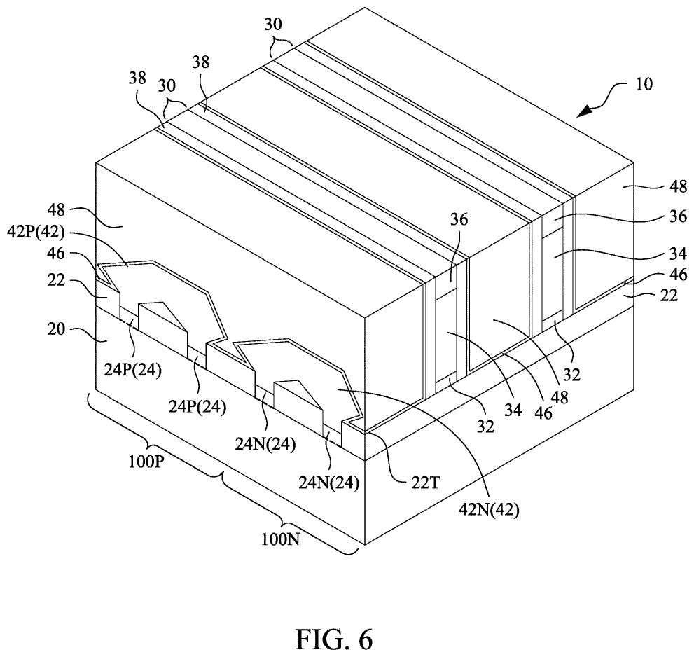

FIG. 6 illustrates a perspective view of the structure after the formation of Contact Etch Stop Layer (CESL) 46 and Inter-Layer Dielectric (ILD) 48. The respective process is illustrated as process 214 in the process flow 200 as shown in FIG. 23. In accordance with some embodiments of the present disclosure, CESL 46 may be formed of or comprise silicon oxide, silicon nitride, silicon carbide, silicon carbonitride, or the like, or combinations thereof. CESL 46 may be formed using a conformal deposition method such as ALD or CVD, for example. ILD 48 may include a dielectric material formed using, for example, FCVD, spin-on coating, CVD, or another deposition method. ILD 48 may also be formed of an oxygen-containing dielectric material, which may be a silicon-oxide based dielectric material such as silicon oxide, Phospho-Silicate Glass (PSG), Boro-Silicate Glass (BSG), Boron-Doped Phospho-Silicate Glass (BPSG), or the like.

A planarization process such as a Chemical Mechanical Polish (CMP) process or a mechanical grinding process may be performed to level the top surfaces of ILD 48, dummy gate stacks 30, and gate spacers 38 with each other.

Referring to FIG. 7A, the dummy gate stacks 30 are removed, which may be achieved through a plurality of etching process. The respective process is illustrated as process 216 in the process flow 200 as shown in FIG. 23. The spaces left by the removed dummy gate stacks 30 are referred to as openings (or trenches) 50. The etching is performed until the protruding fins 24′P and 24′N (refer to FIG. 2) are exposed to openings 50.

FIG. 7B illustrates a cross-sectional view of the structure in FIG. 7A, wherein the cross-section may be the cross-section 7B-7B in FIG. 7A. FIG. 7A shows the device regions 100P and 100N on the left side of FIG. 7B. The transistors to be formed in these device regions may have their gate electrodes electrically interconnected. FIG. 7B further includes device regions 100P and 100N on the right side of the figure. The transistors to be in these device regions may also have their gate electrodes electrically interconnected. The interconnected (combined) gate stacks that will be formed on the left side of FIG. 7B will be electrically insulated from the interconnected (combined) gate stacks that will be formed on the right side of FIG. 7B.

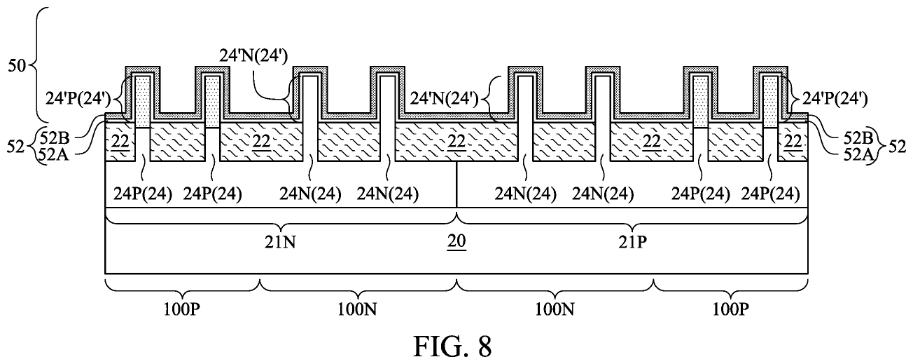

Referring to FIG. 8, gate dielectrics 52 are formed. The respective process is illustrated as process 218 in the process flow 200 as shown in FIG. 23. Gate dielectrics 52 include interfacial layers 52A and high-k dielectric layers 52B. Interfacial layers 52A may include silicon oxide. In accordance with some embodiments, interfacial layers 52A is formed through a deposition process, a thermal oxidation process, a chemical oxidation process, or the like. High-k dielectric layers 52B may include a high-k dielectric material such as hafnium oxide, zirconium oxide, lanthanum oxide, and/or the like. The formation process may include a conformal deposition process such as Atomic Layer Deposition (ALD), Chemical Vapor Deposition (CVD), or the like.

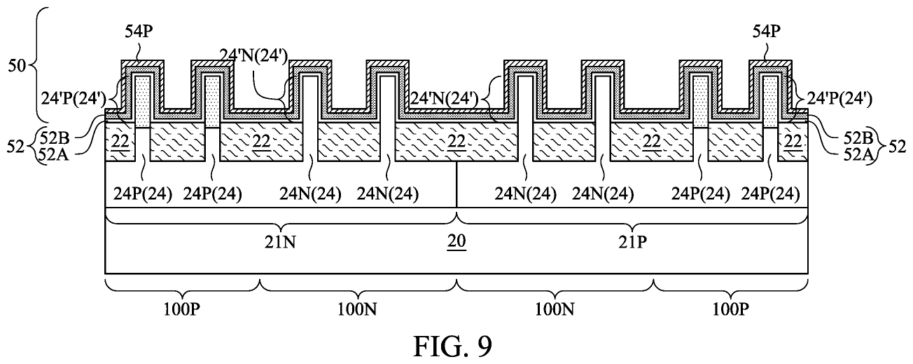

Referring to FIG. 9, p-type work-function (PWF) layer 54P is formed. The respective process is illustrated as process 220 in the process flow 200 as shown in FIG. 23. P-type work-function layer 54P may have a high work function suitable for forming PMOS devices, which work function may be between about 4.9 eV and about 5.2 eV, and may be close to, or equal to, the band-edge work function of about 5.2 eV. For example, p-type work-function layer 54P may comprise TiN, TaN, WCN, MOCN, Pt, Pd, Ni, Au, or the like, or combinations thereof. P-type work-function layer 54P is deposited as a blanket layer, and includes some portions in device regions 100P and some portions in device region 100N. The formation process may include a conformal deposition process such as ALD, CVD, or the like.

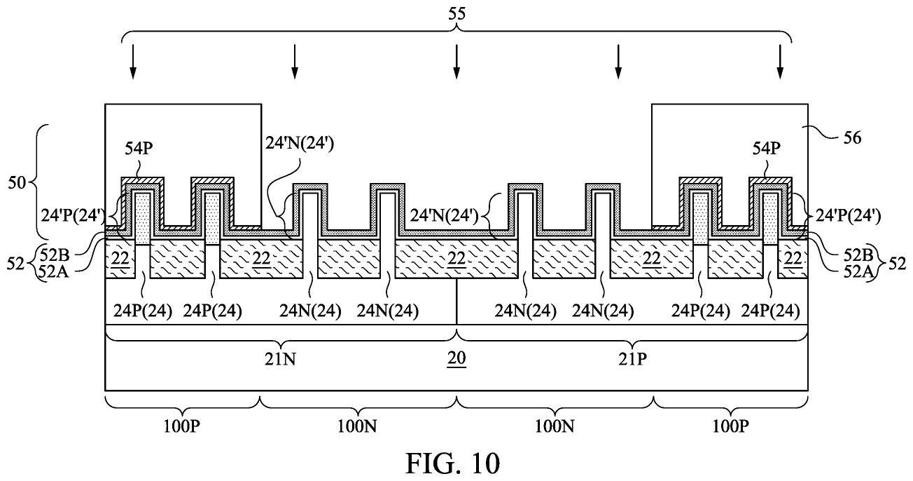

Referring to FIG. 10, etching mask 56 is formed and patterned. Etching mask 56 may include a photoresist, and may have a single layer structure, a tri-layer structure, or the like. Etching mask 56 is alternatively referred to as photoresist 56. There may be (or may not be) a metal hard mask (not shown) underlying the etching mask 56 and over the p-type work-function layer 54P. Etching mask 56 may be a conformal layer that covers the portions of the p-type work-function layer 54P in p-type device region 100P, and leaves the portions of the p-type work-function layer 54P in n-type device region 100N exposed.

An etching process 55 is then performed to etch the metal hard mask (if formed) and the p-type work-function layer 54P. The respective process is illustrated as process 222 in the process flow 200 as shown in FIG. 23. Accordingly, the p-type work-function layer 54P is removed from the n-type device region 100N, and left in the p-type device region 100P.

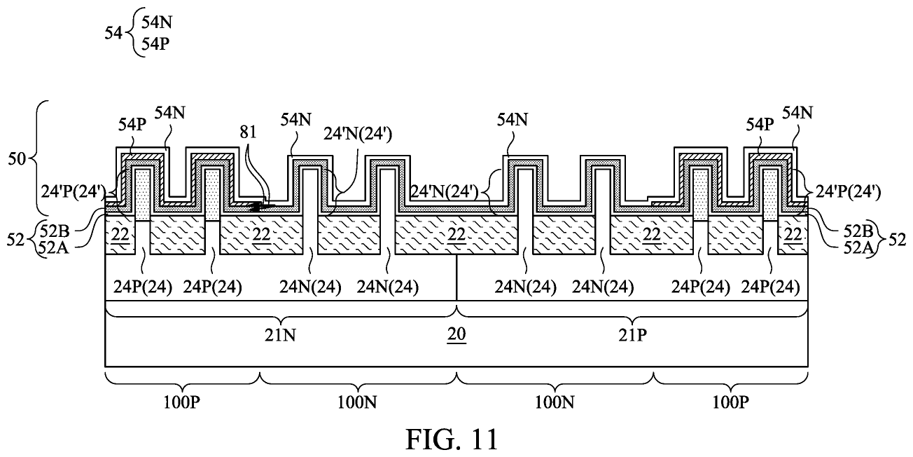

Referring to FIG. 11, n-type work-function (NWF) layer 54N is deposited through a conformal deposition process such as an ALD process, a CVD process, or the like. The respective process is illustrated as process 224 in the process flow 200 as shown in FIG. 23. N-type work-function layer 54N may have a low work function suitable for forming NMOS devices, which work function may be between about 4.0 eV and about 4.4 eV, and may be a band-edge work function of about 4.1 eV. For example, n-type work-function layer 54N may comprise an aluminum-containing conductive material such as TiAlC, TiAlN, TaAlC, TaAlN, or the like, or combinations thereof.

N-type work-function layer 54N is deposited as a blanket layer, and include some portions in device regions 100P and some portions in device regions 100N. The portions of the n-type work-function layer 54N in device regions 100P are formed over the p-type work-function layer 54P.

In accordance with these embodiments, the thickness of p-type work-function layer 54P is great enough, for example, greater than about 2 nm or about 3 nm, so that the n-type work-function layer 54N is far enough from the channel regions of the p-type transistors, and has little or no effect on the threshold voltage of the respective p-type transistors. The p-type work-function layer 54P thus dominates the work function of the respective p-type transistors. Accordingly, the portions of the n-type work-function layer 54N in device regions 100P are alternatively referred to as the extension portions of the n-type work-function layer 54N. Throughout the description, the p-type work-function layer 54P and the n-type work-function layer 54N are individually and connectively referred to as work-function layer(s) 54.

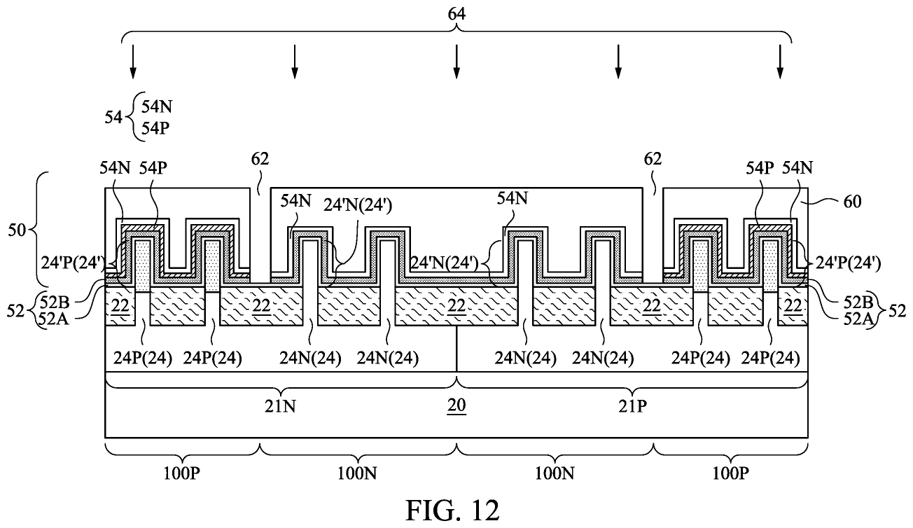

Referring to FIG. 12, etching mask 60 is formed and patterned. Etching mask 60 may include a photoresist, and may have a single layer structure, a tri-layer structure, or the like. Etching mask 60 is alternatively referred to as photoresist 60. Etching mask 60 covers the portions of the n-type work-function layer 54N in both of p-type device region 100P and n-type device region 100N. The openings 62 in etching mask 60 are aligned to the boundary regions of p-type device regions 100P and their respective neighboring n-type device regions 100N.

An etching process 64 is then performed to etch the portions of n-type work-function layer 54N and p-type work-function layer 54P exposed through openings 62. The respective process is illustrated as process 226 in the process flow 200 as shown in FIG. 23. The etched parts may be in the boundary regions where the n-type device regions 100N join the respective neighboring p-type device regions 100P. Accordingly, the etching process 64 is referred to as a Cut-Metal-Boundary (CMB) process. The edges of p-type work-function layer 54P may be directly underlying and aligned to openings 62. Accordingly, after the-type work-function layer 54N is etched, some edge parts of the p-type work-function layer 54P are exposed to openings 62, and are also etched.

Next, high-k dielectric layer 52B is etched to reveal interfacial layer 52A, so that openings 62 extend into high-k dielectric layer 52B. In accordance with some embodiments, the etching process may be performed using a chlorine-containing etching gas such as Cl₂ or other applicable gas(es) as an etching gas. In accordance with some embodiments, by controlling ventilation time and/or etching/ventilation cycles, the etching process 64 may be stopped on interfacial layer 52A, with the interfacial layer 52A being used as an etch stop layer.

In above-discussed embodiments, a p-type work-function layer 54P is deposited first, and is patterned and removed from the n-type device region 100N, and n-type work-function layer 54N is deposited over the remaining portion of the p-type work-function layer 54P. In accordance with alternative embodiments, the sequence of the deposition of the p-type work-function layer 54P and the n-type work-function layer 54N may be inversed. For example, an n-type work-function layer 54N may be deposited first, and is patterned and removed from the p-type device region 100P, and p-type work-function layer 54P is deposited over the remaining portion of the n-type work-function layer 54N.

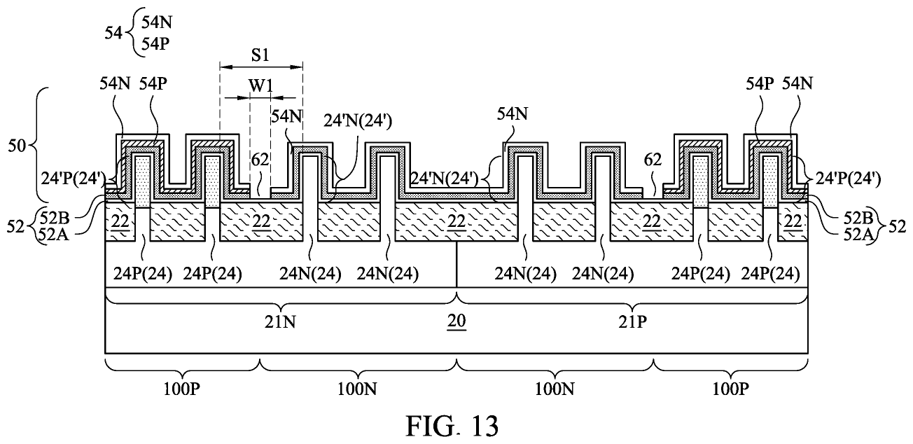

In accordance with some embodiments, after the etching process, a clean up process may be performed to remove the etching mask 60. The resulting structure is shown in FIG. 13. In accordance with some embodiments, oxygen (O₂) and de-ionized (DI) water may be used to remove the polymer produced during the etching process 64.

In accordance with some embodiments, the width W1 of opening 62 in high-k dielectric layer 52 in smaller than about 200 nm, and may be in the range between about 50 nm and about 200 nm. The width W1 may be in the range between about 20 percent and about 80 percent of the fin spacing S1 between the protruding fins on the opposite sides of opening 62.

In accordance with alternative embodiments, when the portions of STI regions 22 directly underlying openings 62 are formed of a material different from the material of interfacial layer 52A, the etching process 64, instead of stopping on interfacial layer 52A, may be stopped on STI regions 22. Openings 62 thus will penetrate through interfacial layer 52A. In accordance with yet alternative embodiments, openings 62 may extend into STI regions 22. In accordance with yet alternative embodiments, the etching process results in the etching of n-type work-function layer 54N and p-type work-function layer 54P, and is stopped on the top surface of high-k dielectric layer 52B.

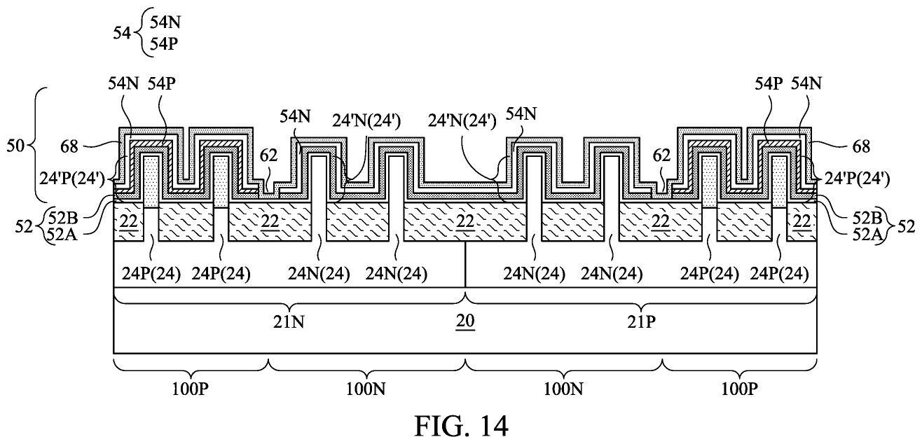

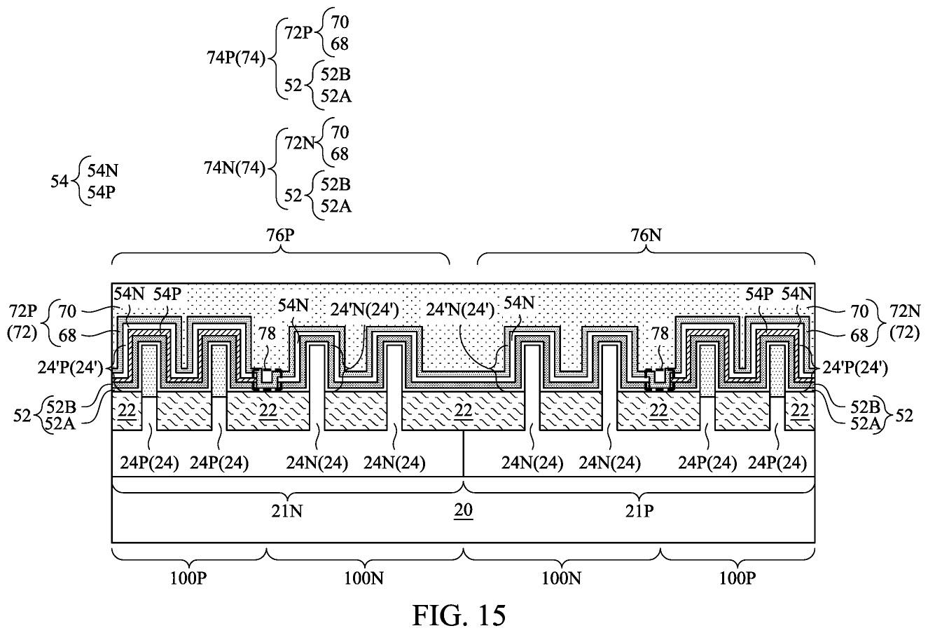

FIGS. 14 and 15 illustrate the filling of the remaining parts of openings 50 in accordance with some embodiments. Referring to FIG. 14, adhesion layer 68 (also referred to as a barrier layer since it also helps in the blocking of inter-diffusion) is deposited. The respective process is illustrated as process 228 in the process flow 200 as shown in FIG. 23. In accordance with some embodiments, adhesion layer 68 comprises TiN, TaN, or the like. The formation process may include a conformal deposition process such as ALD, CVD, or the like in accordance with some embodiments.

Next, as shown in FIG. 15, a filling metal layer 70 is deposited. The respective process is illustrated as process 230 in the process flow 200 as shown in FIG. 23. The formation process may include Physical Vapor Deposition, ALD, CVD, or the like, or combinations thereof. The filling metal layer 70 may comprise tungsten, cobalt, aluminum, nickel, or the like, or alloys thereof. The filling metal layer 70 is deposited until the entire openings 50 (FIG. 7A) are filled.

A planarization process is then performed, so that the portions of the filling metal layer 70 and the adhesion layer 68 higher than the top surfaces of ILD 48 and CESL 46 (FIG. 7A) are removed. The remaining portions of the work-function layers 54 (including p-type work-function layer 54P and N-type work-function layer 54N) and the overlying adhesion layer 68 and filling metal layer 70 are collectively referred to as gate electrodes 72. Gate electrodes 72 include the gate electrode 72P of the resulting p-type transistor 76P and the gate electrode 72N of the resulting N-type transistor 76N. Gate dielectrics 52 and gate electrodes 72 are collectively referred to as gate stacks 74. Gate stacks 74 include the gate stack 74P of the p-type transistor 76P and the gate stack 74N of the N-type transistor 76N.

In accordance with alternative embodiments, instead of forming openings before the formation of adhesion layer 68, openings 62 are formed after the formation of adhesion layer 68. Accordingly, the adhesion layer 68 is also etched-through (in addition to the etching of p-type work-function layer 54P and N-type work-function layer 54N) in the corresponding etching process. The conductive layer(s) (such as filling metal layer 70) that are formed after the formation of openings 62 thus will also penetrate through adhesion layer 68.

As shown in FIG. 15, adhesion layer 68 and filling metal layer 70 include some portions penetrating through (and inside) p-type work-function layer 54P, n-type work-function layer 54N, and high-k dielectric layer 52B to form CMB regions 78. CMB regions 78 comprise sidewalls contacting the sidewalls of p-type work-function layers 54P and n-type work-function layers 54N. The bottom surfaces of CMB regions 78 may be in contact with the top surface of interfacial layer 52A to form horizontal interfaces.

In accordance with alternative embodiments, CMB regions 78 may penetrate through interfacial layer 52A to contact the top surfaces of STI region 22. In accordance with yet alternative embodiments, CMB regions 78 may extend into, and comprise bottom portions inside, STI regions 22.

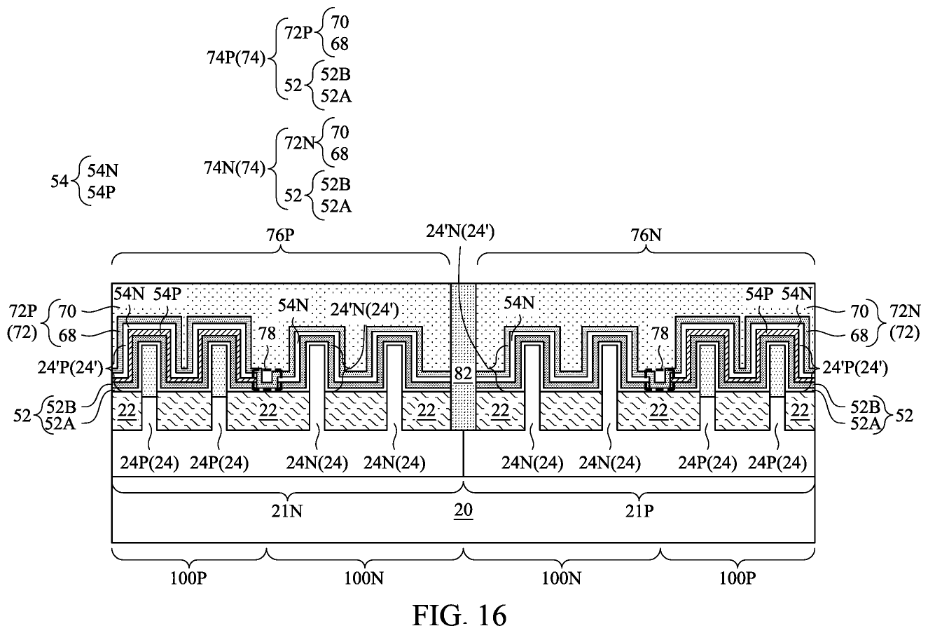

FIG. 16 illustrates the formation of Cut-Metal-Gate (CMG) regions, which process is also referred to as a CMG process. The respective process is illustrated as process 232 in the process flow 200 as shown in FIG. 23. In accordance with some embodiments, the gate stacks 74 may be etched to form a trench (occupied by CMG region 82). The etching process may include one or a plurality of anisotropic etching processes.

In accordance with some embodiments, an STI region 22 may be etched-through, and the underlying semiconductor substrate 20 is exposed. In accordance with alternative embodiments, the etching may be stopped at any level lower than the bottom surface of gate electrodes 72, and may be stopped on the top surface of high-k dielectric layer 52B, on the top surface of STI region 22, or at any intermediate level between the top surface and the bottom surface of STI region 22.

The trench is then filled with a dielectric material such as silicon oxide, silicon nitride, silicon oxynitride, silicon oxycarbide, or the like, or combinations thereof. CMG region 82 is thus formed. The CMG region 82 physically separates the work-functions layers 54 on opposing sides of CMG region 82 from each other.

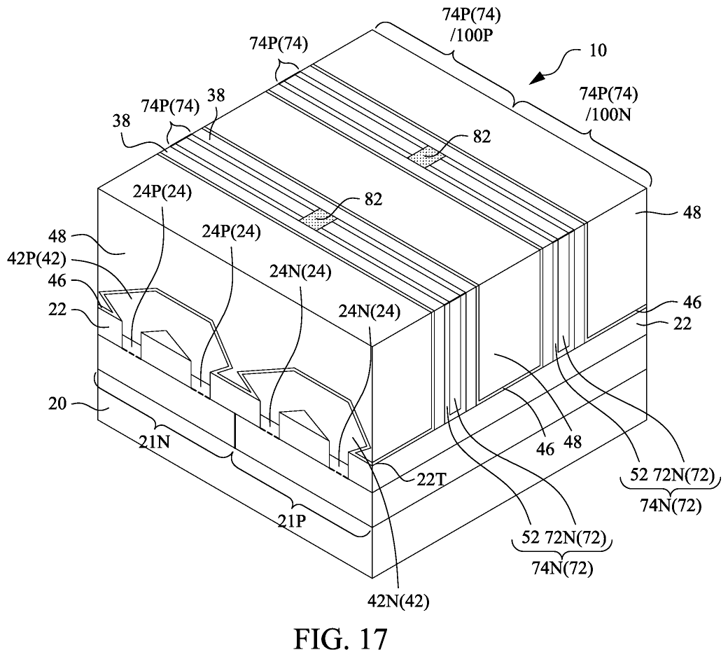

FIG. 17 illustrates a perspective view of the structure shown in FIG. 16. The transistors on the left side (or the right side) of CMG region 82 (FIG. 16) are illustrated. In subsequent processes, more processes may be performed, and the corresponding processes may include forming self-aligned gate hard masks overlapping gate stacks 74. The formation of the self-aligned gate hard masks may include an etching process to recess gate stacks 74, filling the corresponding recesses with a dielectric material(s), and performing a planarization process to remove the portions of the dielectric material higher than the top surface of ILD 48. Source/drain silicide layers, source/drain contact plugs, gate contact plugs, and the like may then be formed to electrically connect to the source/drain region 42 and gate electrodes 72.

Forming CMB regions 78 has some advantageous features. As shown in FIG. 15, if CMB regions 78 are not formed, the structure at the boundary regions of the work-function layers 54 may be the same as shown in FIG. 11, wherein the n-type work-function layer 54N in the device region 100N is laterally close to the p-type work-function layer 54P and the high-k dielectric layer 52B in device region 100P.

In accordance with some embodiments in which the n-type work-function layer 54N comprises aluminum, the aluminum tends to diffuse into the p-type work-function layer 54P and the high-k dielectric layer 52B in device region 100P. The diffusion paths are marked by arrows 81 as shown in FIG. 11 as an example. The aluminum diffused from the n-type work-function layer 54N into the p-type work-function layer 54P and the portions of the high-k dielectric layer 52B in device region 100P causes the ability of threshold-voltage-tuning to be lowered. For example, the threshold voltage of the p-type transistor may be adversely increased by about 15 mV to about 20 mV. The speed of the p-type transistor may be adversely dropped by about 1.35% and about 1.75%.

In accordance with some embodiments, by forming the CMB regions 78, the lateral diffusion paths 81 become longer, and the diffusion rate is lower. In addition, the CMB regions 78, which comprise portions of the adhesion layer 68 and the fill metal layer 70, may be dense and thus are difficult for the aluminum to diffuse through them. The diffusion rate is thus also lowered. The adverse increase in the threshold voltage of the p-type transistor is thus at least reduced or eliminated.

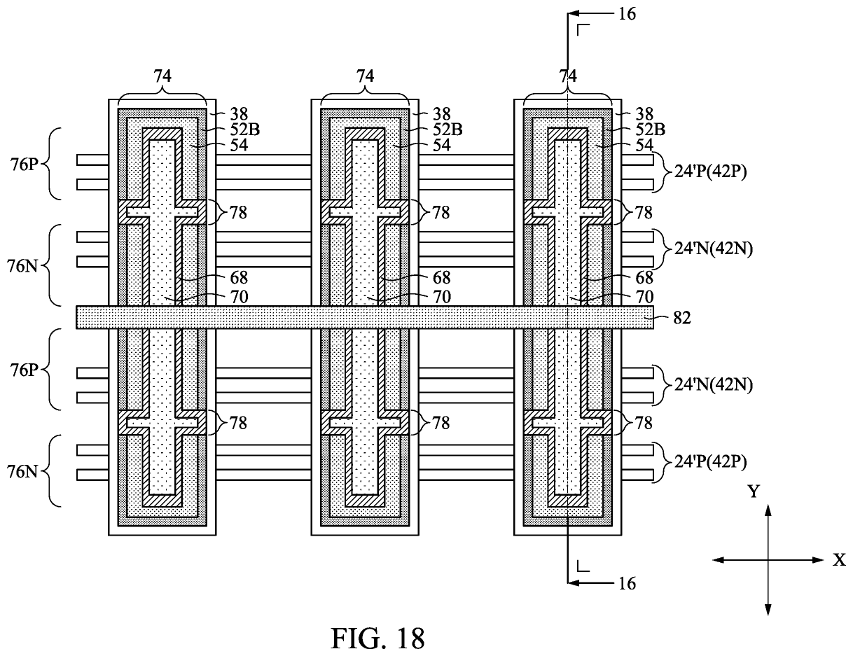

FIG. 18 illustrates a top view of some transistors in accordance with some embodiments. The cross-sectional view as shown in FIG. 16 may be obtained from the cross-section 16-16 as shown in FIG. 18. FIG. 18 illustrates three gate strips that are parallel to each other and cut by the same CMG region 82. In accordance with alternative embodiments, there may be more or fewer gate strips that are parallel to each other and cut by the same CMG region 82.

As shown in FIG. 18, gate stacks 74 have the shape of elongated strips that have longitudinal directions in the illustrated Y-directions. Gate spacers 38 may form rings, which may or may not be broken by CMG regions 82. Each of the high-k dielectric layer 52B, work-function layers 54 (including 54P and 54N), and adhesion layer 68 include vertical portions that form broken rings, which are broken by CMB region 78.

CMB regions 78 are formed between the protruding fins 24′P and 24′N, and extend laterally (in the X-directions) beyond the edges of the corresponding edges of the vertical portions of the corresponding work-function layers 54, and extend into the vertical portions of high-k dielectric layer 52B and the work-function layers 54. In the top view, the CMB regions 78 may be limited by the respective rings formed of gate spacers 38. The CMG regions 82, on the other hand, may cut apart, and may extend to, a plurality of gate stacks.

In accordance with some embodiments, the CMB regions 78 are formed to block the diffusion of aluminum from n-type transistors to neighboring p-type transistors. The CMB regions 78 function effectively for the embodiments in which the n-type transistors are close to their neighboring p-type transistors, for example, with the closest fins of the neighboring transistors having spacings smaller than about 100 nm. For the embodiments in which the spacings between the n-type transistors are large and the diffusion is of a smaller concern, the CMB regions 78 may not be formed.

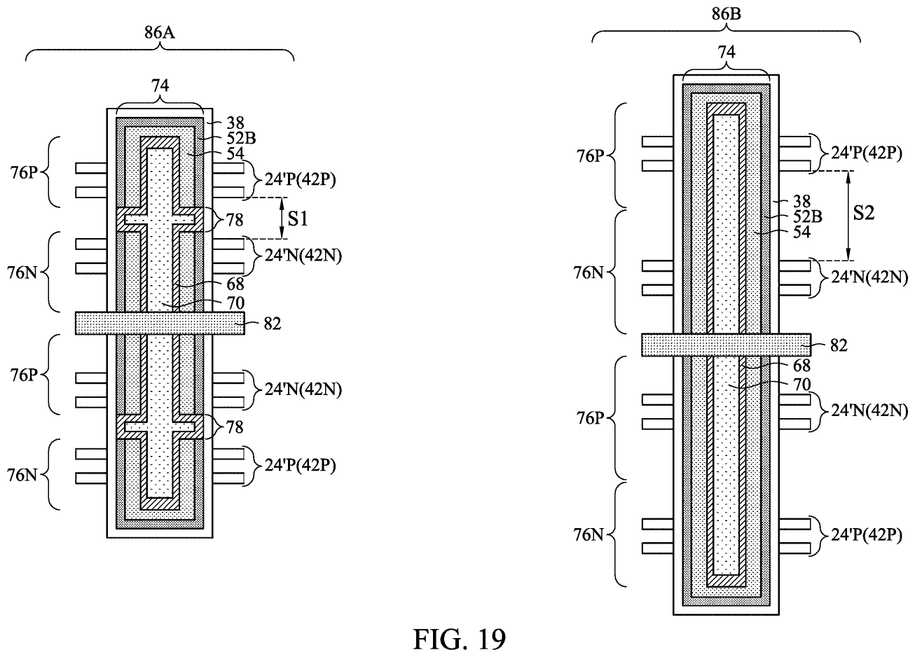

For example, FIG. 19 illustrates two groups of transistors, each including two p-type transistors and two n-type transistors as an example. In the group on the left of the figure (which group is in device region 86A), the spacing S1 between the fins of the n-type transistors and the fins of their neighboring p-type transistors may be smaller than about 200 nm or smaller than about 100 nm. In the group on the right of the figure (which group is in device region 86B), the spacing S2 between the fins of the n-type transistors and the fins of their neighboring p-type transistors is greater than spacing S1. For example, the spacings S2 may be greater than about 200 nm. The ratio S2/S1 is greater than 1.0, and may be greater than about 1.5, greater than about 2.0, 5.0, or greater.

In accordance with some embodiments, the CMB regions 78 are formed in the left group, and are not formed in the right group. Since the spacing S2 has a high value, the aluminum diffusion to the parts of the high-k dielectric layers and p-type work function layers in the p-type transistors is low, and the adverse effect to the threshold voltage of the p-type transistors is low. Accordingly, the CMB regions are not formed.

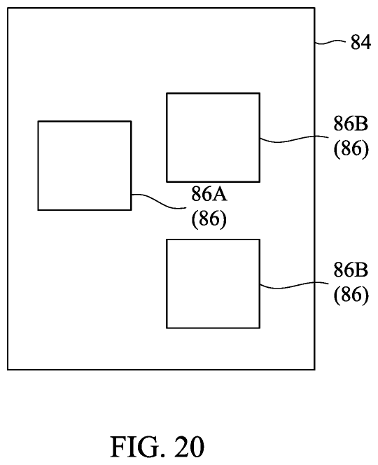

FIG. 20 illustrates a device die 84 in accordance with some embodiments. Device region 86 include device regions 86A and 86B. In the device region 86A, transistors may be formed smaller and having smaller spacings S1 (FIG. 19). CMB regions 78 are thus formed in the device region 86A to separate the neighboring p-type transistors and n-type transistors apart. Device regions 86A may be logic regions having logic circuits, Static Random-Access Memory (SRAM) circuits, or the like. In device region 86B, however, the transistors may be formed larger and having greater spacings S2 (FIG. 19). CMB regions 78 are thus not formed between the neighboring p-type transistors and n-type transistors. Device regions 86A may be IO regions in accordance with some embodiments.

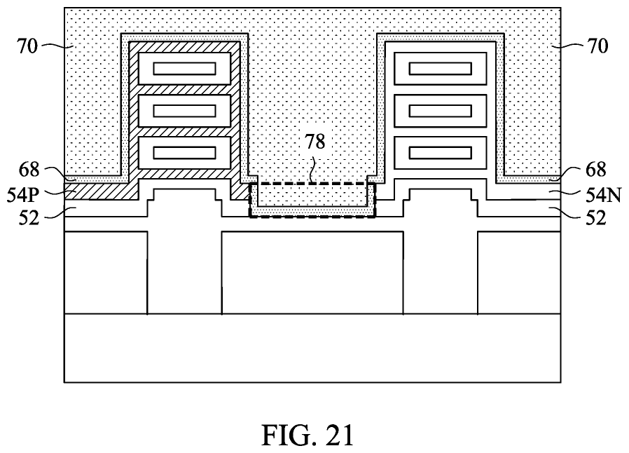

In the above-discussed embodiments, FinFETs are illustrated as examples. The concept of the present application may also be applied to any other types of transistors including, and not limited to, planar transistors, GAA transistors, Complementary Field-Effect Transistors (CFETs) and the like. For example, FIG. 21 illustrates a structure in which a p-type transistor and an n-type transistor are formed, with their gate electrodes physically and electrically connected. CMG region 78 thus is formed to separate the n-type work-function layer 54N apart from the p-type work-function layer 54p and the high-k dielectric layer 52B of the p-type transistor.

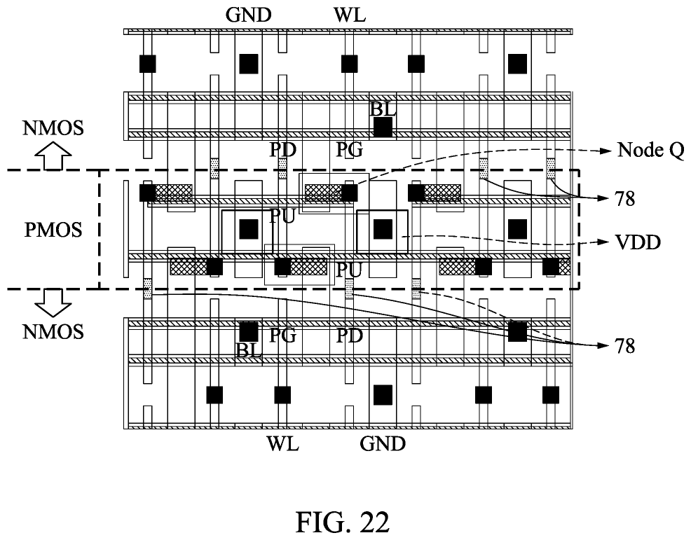

FIG. 22 illustrates a layout of an example SRAM, which includes PMOS and NMOS transistors formed as pull-up (PU) transistors and pull-down (PD) transistors, respectively. The pull-up transistors and pull-down transistors have their gates interconnected to form inverters. Accordingly, CMB regions 78 are formed in the gate strips, and between the gate electrodes of the pull-up transistors and the gate electrodes of the pull-down transistors.

The embodiments of the present disclosure have some advantageous features. By forming CMB regions in the boundary regions of gate stacks of closely located transistors, the adverse effect caused by diffusion is reduced. For example, by forming the CMB regions to separate the n-type work-function layers of the n-type transistors apart from the p-type work-function layers and the high-k dielectric layer of the p-type transistors, the diffusion of aluminum to the p-type work-function layers and the high-k dielectric layer of the p-type transistors is reduced. The adverse increase of the threshold voltages of the p-type transistors is reduced.

In accordance with some embodiments of the present disclosure, a method comprises forming a first gate dielectric and a second gate dielectric over a first semiconductor region and a second semiconductor region, respective; forming a first work-function layer comprising a first portion and a second portion over the first gate dielectric and the second gate dielectric, respectively; patterning the first work-function layer to remove the second portion of the first work-function layer; forming a second work-function layer comprising a first portion and a second portion over the first gate dielectric and the second gate dielectric, respectively, wherein the first portion of the second work-function layer is further over the first portion of the first work-function layer; performing an etching process to etch the second work-function layer and a part of the first portion of the first work-function layer to form an opening; and depositing a conductive layer over the second work-function layer, wherein the conductive layer is filled into the opening.

In an embodiment, the forming the first work-function layer comprises depositing a p-type work-function layer, and the forming the second work-function layer comprises depositing an n-type work-function layer. In an embodiment, the depositing the n-type work-function layer comprises depositing an aluminum-containing conductive layer. In an embodiment, the depositing the conductive layer comprises depositing an adhesion layer; and depositing a filling metal layer over the adhesion layer. In an embodiment, the depositing the adhesion layer comprises depositing a titanium nitride layer.

In an embodiment, the adhesion layer partially fills the opening. In an embodiment, the method further comprises forming an etching mask comprising an additional opening, wherein the etching mask is used for the etching process, wherein the additional opening overlaps an edge of the first work-function layer, and the second work-function layer contacts the edge of the first work-function layer, and wherein the opening is directly underlying the additional opening. In an embodiment, the etching process is performed using an interfacial layer in the first gate dielectric and the second gate dielectric as an etch stop layer.

In an embodiment, the first portion of the first work-function layer and the first portion of the second work-function layer collectively form parts of a first gate stack of a first transistor, and wherein the second portion of the second work-function layer forms a part of a second gate stack of a second transistor. In an embodiment, the method further comprises etching the conductive layer and the first work-function layer to form a trench; and filling the trench with a dielectric material to form a cut-metal-gate region.

In accordance with some embodiments of the present disclosure, a structure comprises a first semiconductor region; a first gate dielectric over the first semiconductor region; a first work-function layer over the first gate dielectric; a second semiconductor region; a second gate dielectric over the second semiconductor region; a second work-function layer over the second gate dielectric; and a conductive layer comprising a first portion overlapping the first work-function layer; a second portion overlapping the second work-function layer; and a middle portion joining the first portion to the second portion, wherein the middle portion contacts a first edge of the first work-function layer and a second edge of the second work-function layer, and wherein the middle portion physically contacts the first gate dielectric.

In an embodiment, the conductive layer comprises a titanium nitride layer. In an embodiment, the first work-function layer comprises a p-type work-function layer, and the second work-function layer comprises an n-type work-function layer. In an embodiment, the second work-function layer comprises aluminum therein. In an embodiment, the structure further comprises an extension portion of the second work-function layer overlapping the first work-function layer, wherein the extension portion is further underlying the first portion of the conductive layer.

In an embodiment, the first work-function layer and the second work-function layer are comprised in a first transistor and a second transistor, respectively. In an embodiment, the first semiconductor region is spaced apart from the second semiconductor region by a spacing, and wherein the middle portion of the conductive layer has a width in a range between about 20 percent and about 80 percent of the spacing. In an embodiment, the conductive layer comprises an adhesion layer; and a filling metal layer over the adhesion layer.

In accordance with some embodiments of the present disclosure, a structure comprises a p-type transistor comprising a first semiconductor fin; a first gate dielectric over the first semiconductor fin; and a first work-function layer over the first gate dielectric; an n-type transistor comprising a second semiconductor fin; a second gate dielectric over the second semiconductor fin, wherein the first gate dielectric and the second gate dielectric comprise an interfacial layer and a high-k dielectric layer over the interfacial layer; and a second work-function layer over the second gate dielectric; and a combined gate electrode comprising a first gate electrode of the p-type transistor and a second gate electrode of the n-type transistor, wherein the combined gate electrode comprises a portion in physical contact with the first work-function layer, the second work-function layer, and the interfacial layer.

In an embodiment, the portion of the combined gate electrode physically contacts edges of parts of the high-k dielectric layer on opposing sides of the portion of the combined gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a first transistor comprising:
a first semiconductor region;
a first gate dielectric over the first semiconductor region;
a first work-function layer over the first gate dielectric; and
a first conductive layer over the first work-function layer; and
a second transistor comprising:
a second semiconductor region;
a second gate dielectric over the second semiconductor region;
a second work-function layer over the second gate dielectric, wherein the first work-function layer and the second work-function layer comprise a same material, and are physically separated from each other; and
a second conductive layer over the second work-function layer, wherein the first conductive layer and the second conductive layer are parts of a continuous conductive layer.

2. The structure of claim 1, wherein the first work-function layer and the second work-function layer are n-type work function layers.

3. The structure of claim 2, wherein the first work-function layer and the second work-function layer comprise aluminum therein.

4. The structure of claim 1, wherein the first transistor further comprises a third work-function layer between the first work-function layer and the first gate dielectric, and the second work-function layer is in physical contact with the second gate dielectric.

5. The structure of claim 1, wherein the first transistor and the second transistor have opposite conductivity types.

6. The structure of claim 1, wherein the first work-function layer and the second work-function layer are physically separated from each other by a cut-metal-boundary portion of the continuous conductive layer.

7. The structure of claim 6, wherein:
the first gate dielectric comprises a first interfacial layer, and a first high-k dielectric layer over the first interfacial layer; and
the second gate dielectric comprises a second interfacial layer, and a second high-k dielectric layer over the second interfacial layer, and wherein the cut-metal-boundary portion of the continuous conductive layer separates the first high-k dielectric layer from the second high-k dielectric layer.

8. The structure of claim 7, wherein the cut-metal-boundary portion contacts a top surface of an intermediate interfacial layer that connects the first interfacial layer to the second interfacial layer.

9. The structure of claim 7, wherein the cut-metal-boundary portion of the continuous conductive layer further separates the first interfacial layer from the second interfacial layer.

10. A structure comprising:
a first semiconductor region;
a first gate dielectric over the first semiconductor region;
a first work-function layer over the first gate dielectric;
a second semiconductor region;
a second gate dielectric over the second semiconductor region;
a second work-function layer over the second gate dielectric;
a conductive layer comprising:
a first portion overlapping the first work-function layer; and
a second portion overlapping the second work-function layer; and
a cut-metal-boundary region between the first work-function layer and the second work-function layer, wherein the cut-metal-boundary region physically contacts a first edge of the first work-function layer and a second edge of the second work-function layer.

11. The structure of claim 10, wherein the first work-function layer and the second work-function layer comprise aluminum therein.

12. The structure of claim 10, wherein the cut-metal-boundary region comprises a same material as the conductive layer.

13. The structure of claim 10, wherein the conductive layer comprises:
an adhesion layer; and
a filling metal layer over the adhesion layer, wherein the cut-metal-boundary region comprises a portion of the adhesion layer.

14. The structure of claim 13, wherein the cut-metal-boundary region further comprises a portion of the filling metal layer.

15. The structure of claim 10 further comprising a third work-function layer between the first gate dielectric and the first work-function layer.

16. The structure of claim 15, wherein the second gate dielectric physically contacts the second work-function layer.

17. A structure comprising:
a p-type transistor comprising:
a first semiconductor fin;
a first gate dielectric over the first semiconductor fin;
a p-type work-function layer over the first gate dielectric;
a first n-type work-function layer over the p-type work-function layer, wherein the first n-type work-function layer comprises aluminum therein; and
a first conductive layer over the first n-type work-function layer;
an n-type transistor comprising:
a second semiconductor fin;
a second gate dielectric over the second semiconductor fin;
a second n-type work-function layer over the second gate dielectric, wherein the second n-type work-function layer comprises aluminum therein; and
a second conductive layer over the second n-type work-function layer, wherein the first conductive layer is electrically connected to the second conductive layer; and
a cut-metal-boundary region separating the p-type work-function layer and the first n-type work-function layer from the second n-type work-function layer.

18. The structure of claim 17, wherein the cut-metal-boundary region comprises same materials and a same structure as the first conductive layer and the second conductive layer.

19. The structure of claim 17, wherein the cut-metal-boundary region, the first conductive layer, and the second conductive layer comprise a first adhesion layer, a second adhesion layer, and a third adhesion layer, respectively, wherein the first adhesion layer, the second adhesion layer, and the third adhesion layer are interconnected as a continuous layer.

20. The structure of claim 19, wherein the continuous layer comprises a titanium nitride layer.
